(19) United States
(12) Patent Application Publication
(10) Pub. No.: US 2024/0215257 A1
(43) Pub. Date: Jun. 27, 2024

(54) FERROELECTRIC MEMORY DEVICE AND METHOD FOR FORMING THE SAME

(71) Applicant: Wuxi Smart Memories Technologies Co., Ltd., Wuxi (CN)

(72) Inventors: Meilan Guo, Wuxi (CN); Yushi Hu, Wuxi (CN); Zhenyu Lu, Wuxi (CN)

(73) Assignee: Wuxi Smart Memories Technologies Co., Ltd., Wuxi (CN)

(21) Appl. No.: 18/595,968

(22) Filed: Mar. 5, 2024

Related U.S. Application Data
(63) Continuation of application No. PCT/CN2021/117074, filed on Sep. 8, 2021.

(51) Int. Cl. H10B 53/30; H10B 53/40

(52) U.S. Cl. CPC H10B 53/30; H10B 53/40

(57) ABSTRACT

A memory device includes a plurality of memory cells and a routing interconnection structure in electric contact with the memory cells. Each memory cell includes at least one first transistor, a cell interconnection structure formed over the transistor and in electrical contact with the transistor, the cell interconnection structure including a cell plate disposed at a top layer of the cell interconnection structure, and at least one capacitor electrically coupled to the first transistor through the cell interconnection structure. Each capacitor includes a first electrode, a second electrode, and a ferroelectric layer disposed between the first electrode and the second electrode. The routing interconnection structure includes a first conductive layer, and a first via structure disposed on the first conductive layer. The first via structure is in electrical contact with the first electrode through a second conductive layer. The first conductive layer is beneath the second conductive layer.

### CROSS-REFERENCE TO RELATED APPLICATIONS

This application is a continuation of International Application No. PCT/CN2021/117074, filed on Sep. 8, 2021, which is incorporated herein by reference in its entirety.

### BACKGROUND

Embodiments of the present disclosure relate to memory devices and fabrication methods thereof, and specifically relates to ferroelectric memory devices and fabrication methods thereof.

The demand for a non-volatile memory that has low operational voltage, low power consumption, and high-speed operation suitable for various electronic equipment, such as portable terminals and integrated circuit (IC) cards, has increased. Ferroelectric memory, such as ferroelectric RAM (FeRAM or FRAM), uses a ferroelectric material layer to achieve non-volatility. A ferroelectric material has a nonlinear relationship between the applied electric field and the apparent stored charge and thus, can switch polarity in an electric field. Ferroelectric memory's advantages include low power consumption, fast write performance, and great maximum read/write endurance.

### SUMMARY

Embodiments of ferroelectric memory devices and fabrication methods thereof are disclosed herein.

In one aspect, a memory device is disclosed. The memory device includes a plurality of memory cells and a routing interconnection structure in electric contact with the plurality of memory cells. Each memory cell includes at least one first transistor, a cell interconnection structure formed over the at least one transistor and in electrical contact with the at least one transistor, the cell interconnection structure including a cell plate disposed at a top layer of the cell interconnection structure, and at least one capacitor electrically coupled to the at least one first transistor through the cell interconnection structure. Each capacitor includes a first electrode, a second electrode surrounding at least a portion of the first electrode, the second electrode electrically contacting the cell plate, and a ferroelectric layer disposed between the first electrode and the second electrode. The routing interconnection structure includes a first conductive layer, and a first via structure disposed on the first conductive layer. The first via structure is in electrical contact with the first electrode through a second conductive layer. The first conductive layer is beneath the second conductive layer.

In some embodiments, the second conductive layer is disposed on and in direct contact with the first electrode. In some embodiments, the second conductive layer is disposed on and in electric contact with the first electrode through a second via structure. In some embodiments, a first height of the at least one capacitor is equal to or less than a second height of a stack of the first via structure and the second conductive layer.

In some embodiments, the memory device further includes a periphery circuit configured to control operations of the plurality of memory cells. The periphery circuit includes at least one second transistor, and a periphery interconnection structure electrically coupled to the at least one second transistor. A third conductive layer of the periphery interconnection structure is in electric contact with the first conductive layer.

In some embodiments, the third conductive layer and the first conductive layer are extended and directly connected to each other.

In another aspect, a memory device is disclosed. The memory device includes a plurality of memory cells, and a dummy memory cell. Each memory cell includes at least one first transistor, a cell interconnection structure formed over the at least one transistor and in electrical contact with the at least one transistor, the cell interconnection structure including a cell plate disposed at a top layer of the cell interconnection structure, and at least one capacitor electrically coupled to the at least one first transistor through the cell interconnection structure. Each capacitor includes a first electrode, a second electrode surrounding at least a portion of the first electrode, the second electrode electrically contacting the cell plate, and a ferroelectric layer disposed between the first electrode and the second electrode. The dummy memory cell includes at least one second transistor, a first conductive layer disposed above the at least one second transistor, and a first via structure disposed on the first conductive layer. The first via structure is in electrical contact with the first electrode through a second conductive layer. The first conductive layer is beneath the second conductive layer.

In some embodiments, a first region of the first via structure is within a second region of the dummy memory cell in a plan view of the memory device. In some embodiments, the second conductive layer is disposed on and in direct contact with the first electrode. In some embodiments, the second conductive layer is disposed on and in electric contact with the first electrode through a second via structure. In some embodiments, a first height of the at least one capacitor is equal to or less than a second height of a stack of the first via structure and the second conductive layer.

In some embodiments, the memory device further includes a periphery circuit configured to control operations of the plurality of memory cells. The periphery circuit includes at least one third transistor, and a periphery interconnection structure electrically coupled to the at least one third transistor. A third conductive layer of the periphery interconnection structure is in electric contact with the first conductive layer.

In some embodiments, top surfaces of the third conductive layer and the first conductive layer are flush with each other. In some embodiments, the third conductive layer and the first conductive layer are extended and directly connected to each other.

In still another aspect, a method for forming a ferroelectric memory cell is disclosed. A semiconductor structure is formed over a substrate, the semiconductor structure including a cell region, a dummy cell region, and a periphery region. A first interconnection structure is formed over the cell region, a second interconnection structure is formed over the dummy cell region, and a third interconnection structure is formed over the periphery region. The second interconnection structure is in electrical contact with the third interconnection structure. A dielectric layer is formed over the first interconnection structure, the second interconnection structure, and the third interconnection structure. A capacitor is formed in the dielectric layer above the first interconnection structure, and a via structure is formed in the dielectric layer above the second interconnection structure. The capacitor and the via structure are electrically connected through a first conductive layer.

In some embodiments, the capacitor includes a first electrode, a second electrode surrounding at least a portion of the first electrode, and a ferroelectric layer disposed between the first electrode and the second electrode. The conductive layer is in direct contact with the first electrode.

In some embodiments, the first conductive layer is formed over a plurality of capacitors in direct contact with a plurality of first electrodes of the plurality of capacitors, and is formed over the via structure in direct contact with the via structure.

In some embodiments, a cell plate is formed on a topmost layer of the first interconnection structure, and a second conductive layer is formed on a topmost layer of the second interconnection structure. Top surfaces of the cell plate and the second conductive layer are flush with each other.

In some embodiments, the dummy cell region is outside an edge of the cell region in a plan view of the semiconductor structure. In some embodiments, a first height of the capacitor is equal to or less than a second height of a stack of the via structure and the first conductive layer.

### BRIEF DESCRIPTION OF THE DRAWINGS

The accompanying drawings, which are incorporated herein and form a part of the specification, illustrate aspects of the present disclosure and, together with the description, further serve to explain the present disclosure and to enable a person skilled in the pertinent art to make and use the present disclosure.

FIG. 1 illustrates a cross-section of an exemplary ferroelectric memory device, according to some aspects of the present disclosure.

FIGS. 2-3 illustrate plan views of an exemplary ferroelectric memory device at different stages of a manufacturing process, according to some aspects of the present disclosure.

FIG. 4 illustrates a cross-section of another exemplary ferroelectric memory device, according to some aspects of the present disclosure.

FIGS. 5-6 illustrate plan views of an exemplary ferroelectric memory device at different stages of a manufacturing process, according to some aspects of the present disclosure.

FIG. 7 illustrates a cross-section of a further exemplary ferroelectric memory device, according to some aspects of the present disclosure.

FIG. 8 illustrates a cross-section of another exemplary ferroelectric memory device, according to some aspects of the present disclosure.

FIGS. 9-14 illustrate plan views of a further exemplary ferroelectric memory device, according to some aspects of the present disclosure.

FIG. 15 illustrates a flowchart of an exemplary method for forming a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, a “side surface” can generally refer to a surface on the exterior of an object. For example, depending on the embodiment, a side surface can be a sidewall along a horizontal direction (e.g., the x-direction) or a top/bottom surface along a vertical direction (e.g., the z-direction). As used herein, a recess refers to an open space between two boundaries. For example, depending on the embodiment, a recess can be located between two surfaces that are not coplanar with each other, e.g., having a staggered configuration.

A memory cell array of the ferroelectric memory device may include a number of bit lines and a number of word lines extending to cross with each other, and a number of memory cells may be arranged in a matrix at positions corresponding to the respective crossings of the lines. Each memory cell may include at least one memory cell transistor, in which the gate electrode of the memory cell transistor may receive a signal from the word line, and at least one ferroelectric capacitor interposed between the source region of the memory cell transistor and a cell plate line. The ferroelectric capacitor has a residual polarization characteristic to generate positive or negative residual polarizations depending on the high/low relationship between the voltage applied to the ferroelectric capacitor from the bit line via the memory cell transistor and the voltage applied to the ferroelectric capacitor from the cell plate line. Hence, one limitation of the ferroelectric memory device fabrication is the capacitance of the ferroelectric capacitor. Various embodiments in accordance with the present disclosure provide ferroelectric memory devices and fabrication methods thereof that can increase the capacitance of the ferroelectric capacitor.

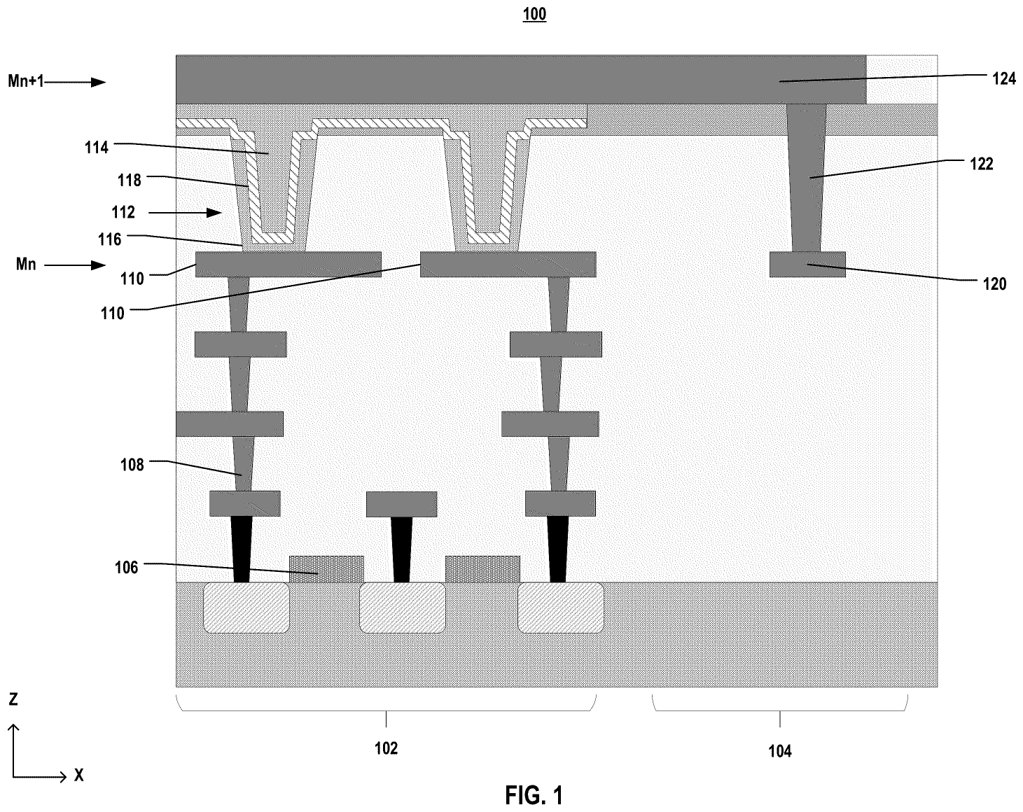

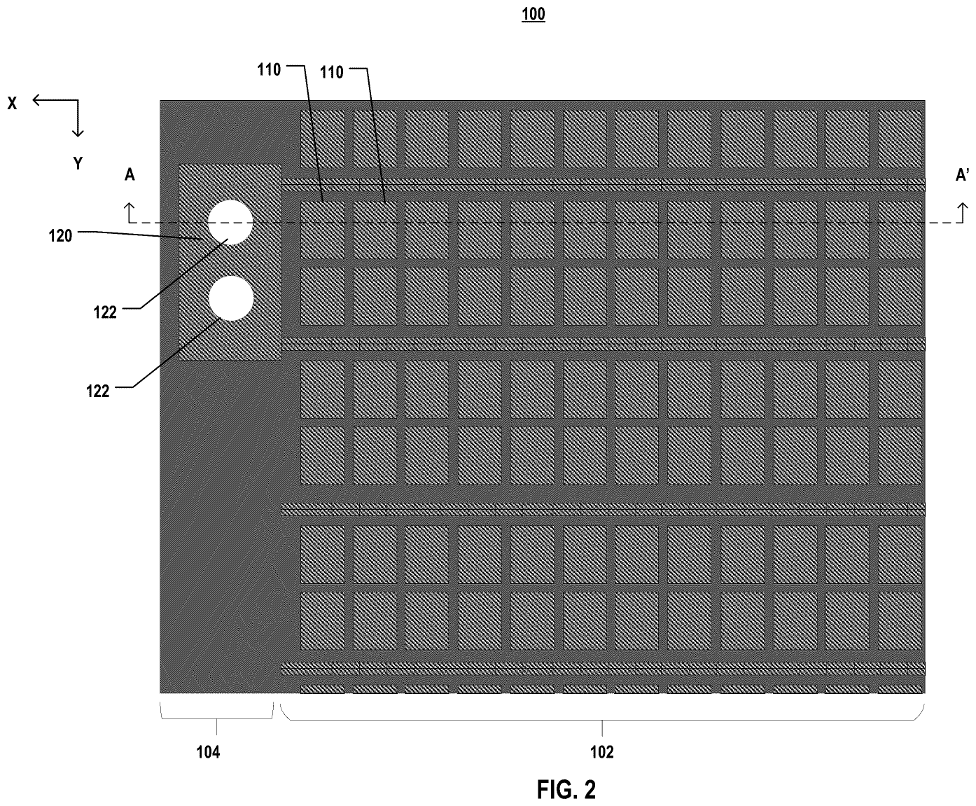

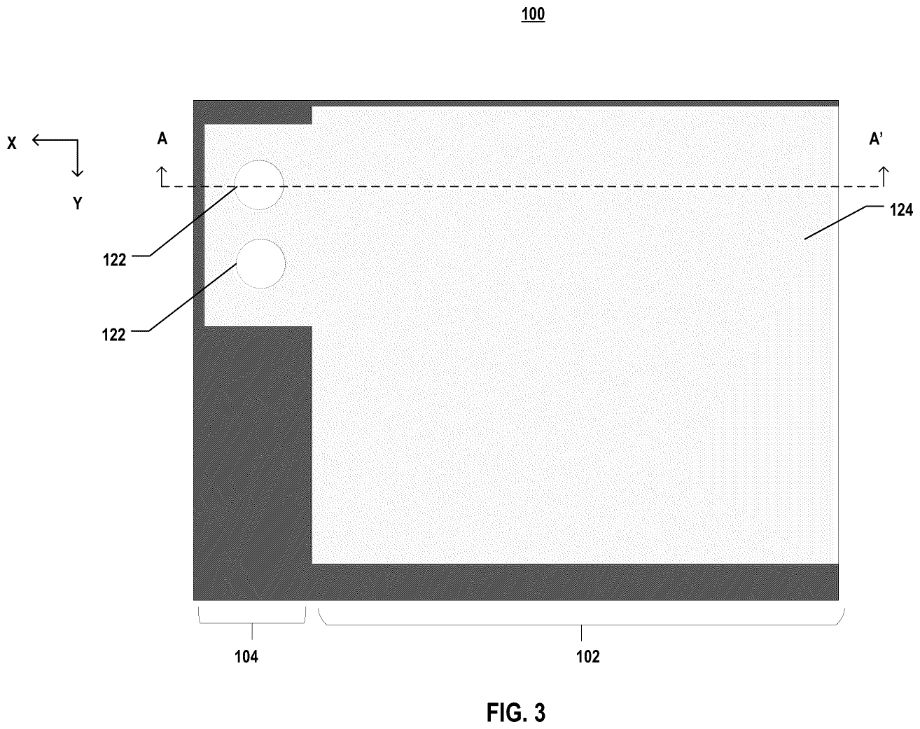

FIG. 1 illustrates a cross-section of an exemplary ferroelectric memory device 100, according to some aspects of the present disclosure. FIGS. 2-3 illustrate plan views of ferroelectric memory device 100 at different stages of a manufacturing process, according to some aspects of the present disclosure. For the purpose of better explaining the present disclosure, the cross-section of ferroelectric memory device 100 in FIG. 1, and the plan views of ferroelectric memory device 100 in FIGS. 2-3 will be described together. FIG. 1 represents the cross-section of ferroelectric memory device 100 along the line AA′ in FIGS. 2-3.

Ferroelectric memory device 100 includes at least one memory cell 102 and at least one routing interconnection structure 104. Memory cell 102 includes at least one transistor 106, and an interconnection structure 108 disposed on transistor 106. In some embodiments, interconnection structure 108 may include one or more than one interconnection layers, as shown in FIG. 1. In some embodiments, interconnection structure 108 may electrically connect one of the terminals of transistor 106. In some embodiments, interconnection structure 108 may electrically connect the source/drain terminal of transistor 106.

A conductive plate 110 is formed over interconnection structure 108, or at the topmost layer of interconnection structure 108. In some embodiments, conductive plate 110 may be the cell landing island of ferroelectric memory device 100. At least one capacitor 112 is formed on conductive plate 110. Ferroelectric memory device 100 may include a plurality of memory cell 102, and each memory cell 102 may be the storage element of ferroelectric memory device 100, and may include various designs and configurations. FIG. 1 shows a “2T-2C” ferroelectric memory cell structure that includes two transistors and two capacitors. However, the amount of the transistors and/or the capacitors in ferroelectric memory device 100 is not limited thereto, and other suitable designs of ferroelectric memory cell structures, e.g., 1T-1C or nT-nC ferroelectric memory cell, are in the scope of the present disclosure.

Capacitor 112 is electrically coupled to transistor 106 through interconnection structure 108 and conductive plate 110. Capacitor 112 includes an electrode 114, and an electrode 116 surrounding at least a portion of electrode 114. In some embodiments, electrode 116 electrically contacts conductive plate 110. In some embodiments, electrode 116 directly contacts conductive plate 110. A ferroelectric layer 118 is disposed between electrode 114 and electrode 116.

Ferroelectric layer 118 may include oxygen and one or more ferroelectric metals. The ferroelectric metals may include, but not limited to, zirconium (Zr), hafnium (Hf), titanium (Ti), aluminum (Al), or other suitable materials. In some embodiments, ferroelectric layer 118 may include oxygen and two or more ferroelectric metals. In some embodiments, ferroelectric layer 118 may include oxygen and a non-metal material such as silicon (Si). Optionally, ferroelectric layer 118 may also include a plurality of dopants formed as a part of the crystal structures. In some embodiments, the dopants compensate for the defects formed during the crystallization of the ferroelectric oxide material to improve the film quality of ferroelectric layer 118. In some embodiments, the dopants are different from the ferroelectric metals in the ferroelectric oxide material and include one or more dopants from one or more of Hf, Zr, Ti, Al, Si, hydrogen (H), oxygen (O), vanadium (V), niobium (Nb), tantalum (Ta), yttrium (Y), and/or lanthanum (La).

Routing interconnection structure 104 may include a conductive layer 120, and a via structure 122, as shown in FIG. 1. In some embodiments, via structure 122 is formed on conductive layer 120. Via structure 122 and electrode 114 are in electrical contact through a conductive layer 124. One conductive layer and one via structure are shown in FIG. 1 to represent routing interconnection structure 104. However, it is understood that more than one stack of conductive layer and via structure may be applied to form routing interconnection structure 104 as well.

As shown in FIG. 1, conductive layer 120 and via structure 122 are designed as the topmost metal structure of routing interconnection structure 104. In some embodiments, conductive plate 110 and conductive layer 120 are the same conductive layer (layer Mₙ in FIG. 1) located beneath conductive layer 124 (layer Mₙ₊₁ in FIG. 1). In some embodiments, conductive plate 110 and conductive layer 120 are formed in the same process. In some embodiments, conductive plate 110 and conductive layer 120 may include the same material. In some embodiments, the top surfaces of conductive plate 110 and conductive layer 120 may be flush with each other. In some embodiments, the height of capacitor 112 is less than or equal to the height of via structure 122. In some embodiments, the height of capacitor 112 is less than the height of a stack of via structure 122 and conductive layer 124.

It is understood that conductive layer 124 may further electrically connect other conductive layers beneath conductive layer 120 based on various applications when more than one stack of conductive layer and via structure are applied to form routing interconnection structure 104.

FIG. 2 illustrates a plan view of layer Mₙ of ferroelectric memory device 100 at different stages of a manufacturing process, according to some aspects of the present disclosure. FIG. 1 represents the cross-section of ferroelectric memory device 100 along the line AA′ in FIG. 2. As shown in FIG. 2, conductive plate 110 and conductive layer 120 may be the same conductive layer, and via structure 122 may be later formed at the dashed line areas on conductive layer 120. In some embodiments, the shape of conductive plate 110 in the plane view may be a rectangle extending along the x-direction, and the extension direction of conductive layer 124 may be also along the same direction (the x-direction).

FIG. 3 illustrates a plan view of layer Mₙ₊₁ of ferroelectric memory device 100 at different stages of a manufacturing process, according to some aspects of the present disclosure. FIG. 1 represents the cross-section of ferroelectric memory device 100 along the line AA′ in FIG. 3. As shown in FIG. 3, conductive layer 124 may cover the area of memory cell 102 and routing interconnection structure 104, fully or partially, and via structure 122 may be formed at the dashed line areas between conductive layer 124 and conductive layer 120.

By electrically connecting conductive layer 124 and conductive layer 120 through via structure 122, the routing path may be designed through conductive layer, e.g., layer Mₙ, beneath the topmost conductive layer, e.g., layer Mₙ₊₁. Furthermore, by electrically connecting conductive layer 124 and conductive layer 120 through via structure 122, capacitor 112 may be formed between the topmost conductive layer, e.g., layer Mₙ₊₁, and the penultimate conductive layer, e.g., layer Mₙ, and electrode 114 can have a routing path through conductive layer 124, via structure 122, and conductive layer 120.

Typically, the topmost metal structure, including via structure 122, of routing interconnection structure 104 or the periphery circuit has the largest thickness among other metal structures. When forming capacitor 112 in the area corresponding to the topmost conductive layer, e.g., layer Mₙ₊₁, and the penultimate conductive layer, e.g., layer Mₙ, capacitor 112 may have a larger cell area and enough charge for memory sensing. Capacitor 112 is, therefore, may be disposed in the area corresponding to one single metal structure layer instead of occupying multiple layers of metal structure. By using this structure, the manufacturing process may be simplified, and the reliability of the memory cells may also be improved.

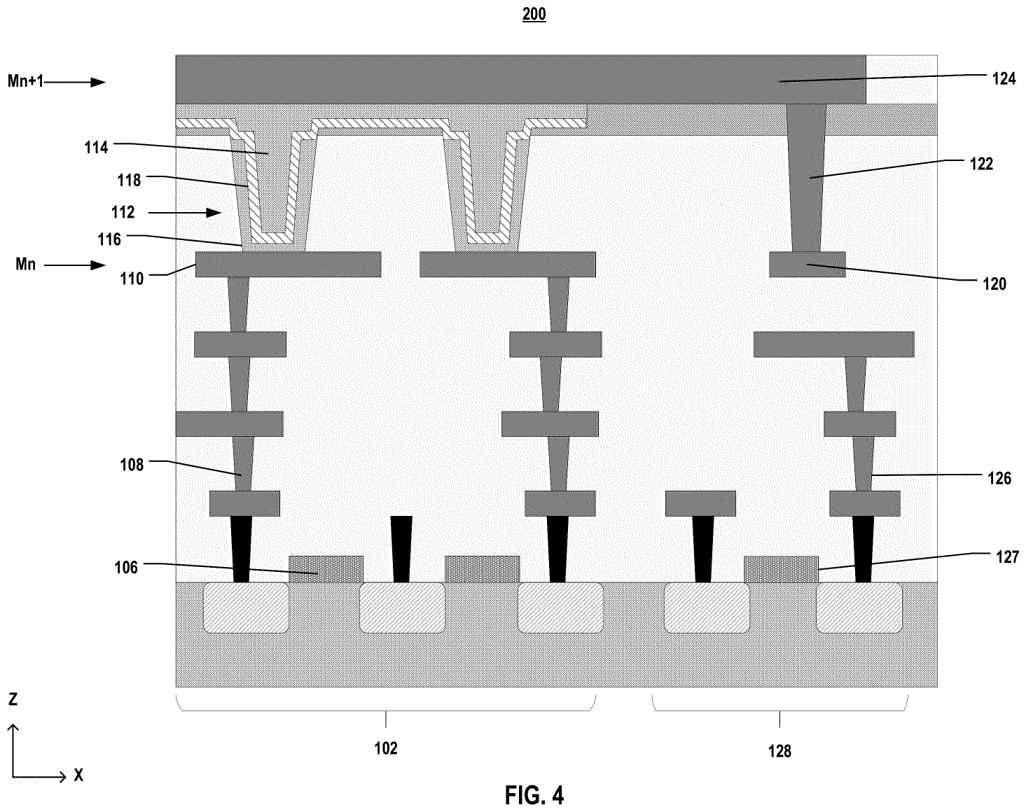

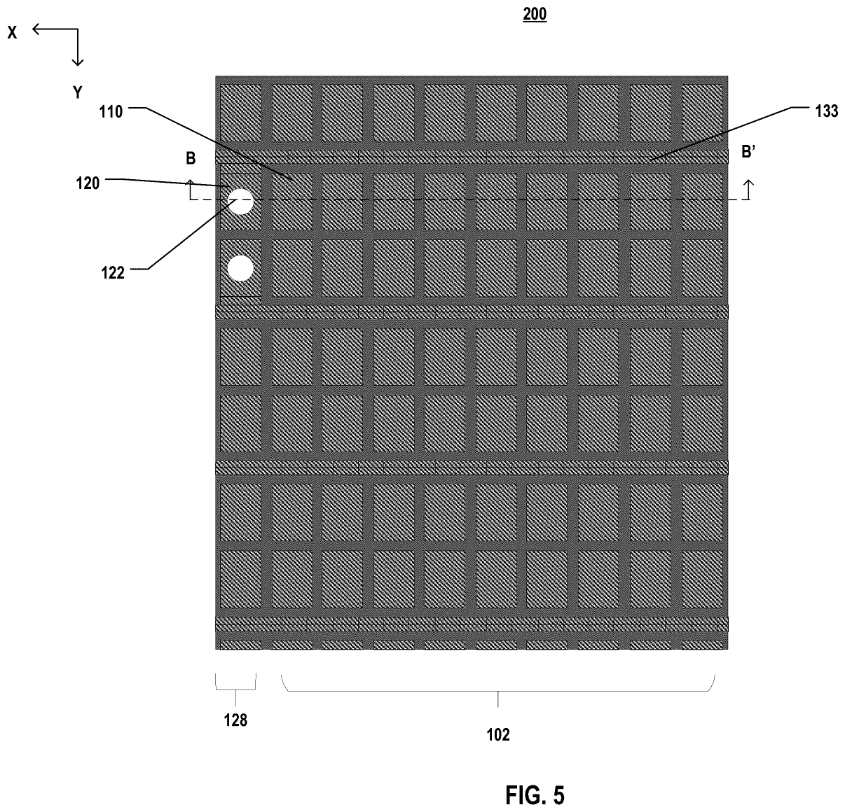

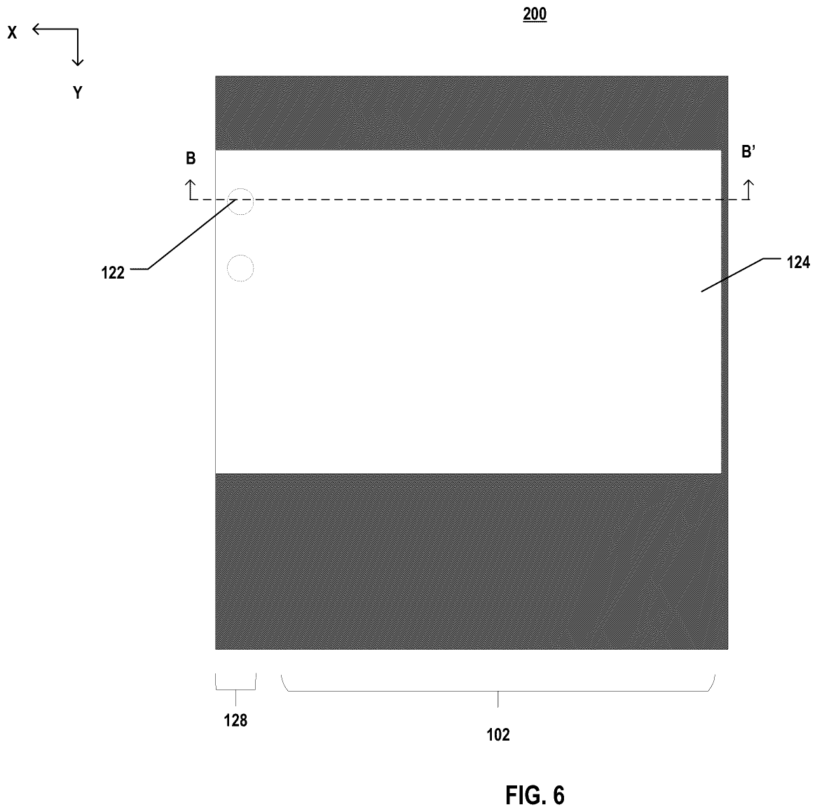

FIG. 4 illustrates a cross-section of an exemplary ferroelectric memory device 200, according to some aspects of the present disclosure. FIGS. 5-6 illustrate plan views of ferroelectric memory device 200 at different stages of a manufacturing process, according to some aspects of the present disclosure. For the purpose of better explaining the present disclosure, the cross-section of ferroelectric memory device 200 in FIG. 4, and the plan views of ferroelectric memory device 200 in FIGS. 5-6 will be described together. FIG. 4 represents the cross-section of ferroelectric memory device 200 along the line BB′ in FIGS. 5-6.

Ferroelectric memory device 200 includes at least one memory cell 102 and at least one dummy memory cell 128. Memory cell 102 may include at least one transistor 106, and interconnection structure 108 may be disposed on transistor 106, as discussed above. Conductive plate 110 is formed over interconnection structure 108, or at the topmost layer of interconnection structure 108. In some embodiments, conductive plate 110 may be the cell landing island of ferroelectric memory device 200. Capacitor 112 is formed on conductive plate 110. Ferroelectric memory device 200 may include a plurality of memory cell 102, and each memory cell 102 may be the storage element of ferroelectric memory device 200, and may include various designs and configurations.

Capacitor 112 is electrically coupled to transistor 106 through interconnection structure 108 and conductive plate 110. Capacitor 112 may include electrode 114, and electrode 116 surrounding at least a portion of electrode 114. In some embodiments, electrode 116 electrically contacts conductive plate 110. In some embodiments, electrode 116 directly contacts conductive plate 110. Ferroelectric layer 118 is disposed between electrode 114 and electrode 116.

Generally, a memory cell array of a semiconductor memory may include a plurality of memory cells arranged in a matrix and wirings (word lines and bit lines) for connecting those memory cells to a word decoder, a sense amplifier, and the like. In the memory cell array, elements and wirings are arranged with higher density, as compared with those in circuits near the memory cell array. In other words, the layout density of the elements and wirings on the inside of the memory cell array is different from that on the outside thereof. Thus, the shapes of the elements and wirings in an inner region of the memory cell array may be different from those in an outer peripheral region because of halation or the like in a fabrication process. Such a difference in the shapes may cause a short failure and a disconnection failure, thus reducing the yield. In order to make the shapes of the elements and wirings in the inner region of the memory cell array the same as those in the outer peripheral region so as to increase the yield, dummy memory cells and/or dummy wirings may be formed in the outer peripheral region of the memory cell array.

Dummy memory cell 128 may include at least one transistor 127, and an interconnection structure 126 may be disposed on transistor 127. Conductive layer 120 may be disposed above transistor 127. In some embodiments, dummy memory cell 128 may have conductive layer 120 electrically connected to interconnection structure 126. In some embodiments, conductive layer 120 may be electrically isolated from interconnection structure 126, as shown in FIG. 4. In some embodiments, dummy memory cell 128 may not include interconnection structure 126.

Since conductive layer 120 and via structure 122 are formed above the region of dummy memory cell 128, the region of conductive layer 120 and via structure 122 is within the region of dummy memory cell 128 in a plan view of ferroelectric memory device 200. In other words, conductive layer 120 and via structure 122 overlaps the region of dummy memory cell 128 in the plan view of ferroelectric memory device 200. In some embodiments, the region of via structure 122 is within the region of dummy memory cell 128 in a plan view of ferroelectric memory device 200. In other words, via structure 122 overlaps the region of dummy memory cell 128 in the plan view of ferroelectric memory device 200. Via structure 122 is disposed on conductive layer 120. Via structure 122 and electrode 114 are in electrical contact through a conductive layer 124. One conductive layer and one via structure are shown in FIG. 4 to represent routing interconnection structure 104. However, it is understood that more than one stack of conductive layer and via structure may be formed above dummy memory cell 128 as well. In some embodiments, conductive layer 124 may be a portion of electrode 114. In some embodiments, electrode 114 may extend along the x-direction to form conductive layer 124.

As shown in FIG. 4, conductive layer 120 and via structure 122 are designed as the topmost metal structure above dummy memory cell 128. In some embodiments, conductive plate 110 and conductive layer 120 are the same conductive layer (layer Mₙ in FIG. 4) located beneath conductive layer 124 (layer Mₙ₊₁ in FIG. 4). In some embodiments, conductive plate 110 and conductive layer 120 are formed in the same process. In some embodiments, conductive plate 110 and conductive layer 120 may include the same material. In some embodiments, the top surfaces of conductive plate 110 and conductive layer 120 may be flush with each other. In some embodiments, the height of capacitor 112 is less than or equal to the height of via structure 122. In some embodiments, the height of capacitor 112 is less than the height of a stack of via structure 122 and conductive layer 124.

It is understood that conductive layer 124 may further electrically connect other conductive layers beneath conductive layer 120 based on various applications when more than one stack of conductive layer and via structure are formed above dummy memory cell 128.

FIG. 5 illustrates a plan view of layer Mₙ of ferroelectric memory device 200 at different stages of a manufacturing process, according to some aspects of the present disclosure. FIG. 4 represents the cross-section of ferroelectric memory device 200 along the line BB′ in FIG. 5. As shown in FIG. 5, conductive plate 110 and conductive layer 120 may be the same conductive layer, and via structure 122 may be later formed at the dashed line areas on conductive layer 120. In addition, as shown in FIG. 5, the dummy cell region (dummy memory cell 128) is outside the edge of the cell region (memory cell 102) in the plan view of ferroelectric memory device 200.

FIG. 6 illustrates a plan view of layer Mₙ₊₁ of ferroelectric memory device 200 at different stages of a manufacturing process, according to some aspects of the present disclosure. FIG. 4 represents the cross-section of ferroelectric memory device 200 along the line BB′ in FIG. 6. As shown in FIG. 6, conductive layer 124 may cover the area of memory cell 102 and dummy memory cell 128, fully or partially, and via structure 122 may be formed at the dashed line areas between conductive layer 124 and conductive layer 120.

By electrically connecting conductive layer 124 and conductive layer 120 through via structure 122, the conductive layer(s) and via(s) above dummy memory cell 128 may be used for the routing path. Since via structure 122 and conductive layer 120 are formed within the dummy cell region (in the plan view), the routing path will not occupy extra area of ferroelectric memory device 200, and the size of ferroelectric memory device 200 will not be affected. In addition, the routing path may be designed through conductive layer, e.g., layer Mₙ, beneath the topmost conductive layer, e.g., layer Mₙ₊₁, and the manufacturing process of layer Mₙ is already required when forming memory cell 102; therefore, no extra process or mask will be added.

Furthermore, by electrically connecting conductive layer 124 and conductive layer 120 through via structure 122, capacitor 112 may be formed between the topmost conductive layer, e.g., layer Mₙ₊₁, and the penultimate conductive layer, e.g., layer Mₙ, and electrode 114 can have a routing path through conductive layer 124, via structure 122, and conductive layer 120.

Typically, the topmost metal structure, including via structure 122 has the largest thickness among other metal structures. When forming capacitor 112 in the area corresponding to the topmost conductive layer, e.g., layer Mₙ₊₁, and the penultimate conductive layer, e.g., layer Mₙ, capacitor 112 may have a larger cell area and enough charge for memory sensing. Capacitor 112 is, therefore, may be disposed in the area corresponding to one single metal structure layer instead of occupying multiple layers of metal structure. By using this structure, the manufacturing process may be simplified, and the reliability of the memory cells may also be improved.

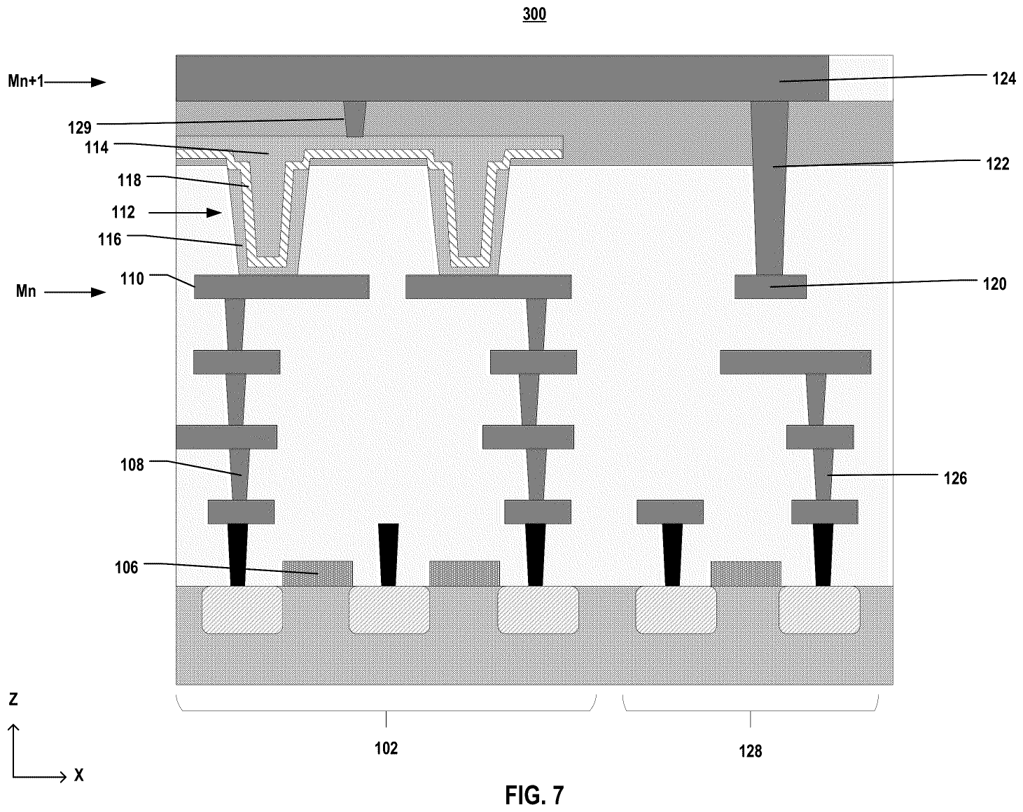

FIG. 7 illustrates a cross-section of a further exemplary ferroelectric memory device 300, according to some aspects of the present disclosure. Ferroelectric memory device 300 is similar to ferroelectric memory device 200, but conductive layer 124 in ferroelectric memory device 300 is connected to electrode 114 through a via structure 129. In some embodiments, conductive layer 124 in ferroelectric memory device 300 may be connected to electrode 114 through more than one via structure 129.

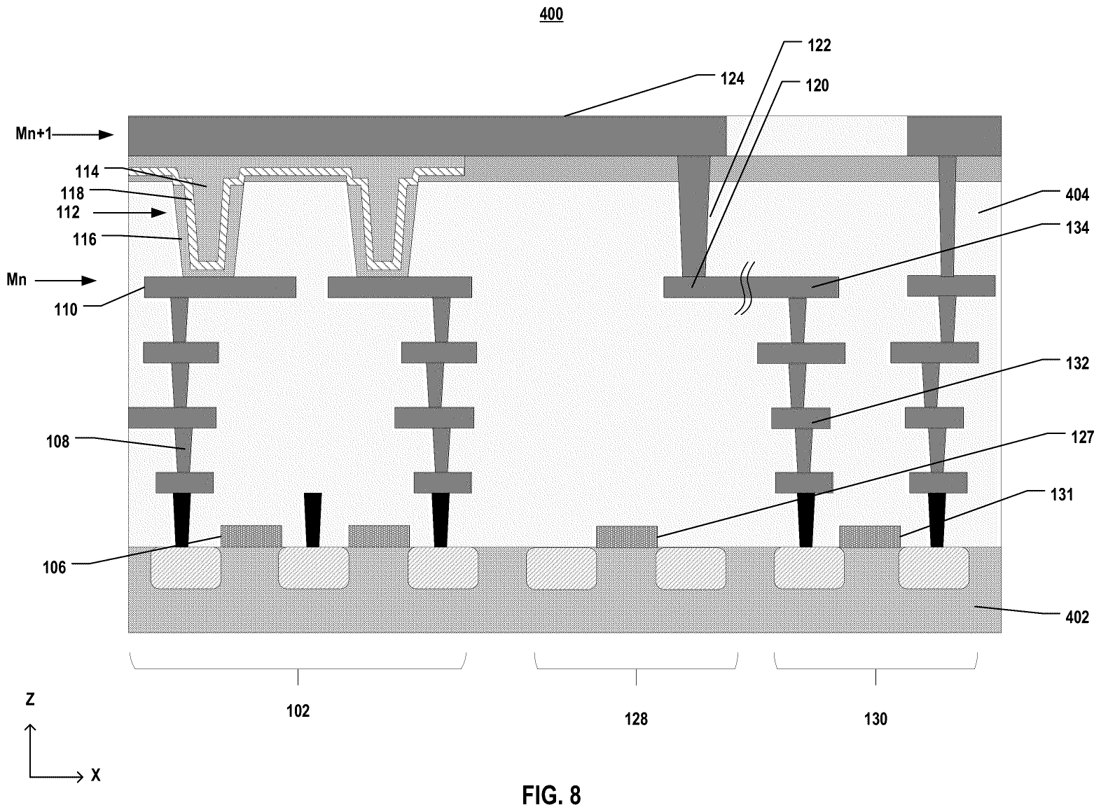

FIG. 8 illustrates a cross-section of another exemplary ferroelectric memory device 400, according to some aspects of the present disclosure. Ferroelectric memory device 400 is similar to ferroelectric memory device 200, and a periphery circuit 130 is further electrically connected to the routing path through conductive layer 120. It is understood periphery circuit 130 may also be applied to ferroelectric memory device 100 by electrically connecting with routing interconnection structure 104 through conductive layer 120. FIG. 8 shows one transistor in periphery circuit 130, however, in actual structure, multiple transistors may be formed in periphery circuit 130.

Periphery circuit 130 is configured to control operations of memory cell 102. Periphery circuit 130 may include at least one transistor 131, and an interconnection structure 132 electrically coupled to transistor 131. In some embodiments, interconnection structure 132 may include one or more than one interconnection layers, as shown in FIG. 4. In some embodiments, interconnection structure 132 may electrically connect one of the terminals of transistor 131. In some embodiments, interconnection structure 132 may electrically connect the source/drain terminal of transistor 131. A conductive plate 134 is formed over interconnection structure 132. In some embodiments, conductive plate 134 may be a metal layer of periphery circuit 130.

As shown in FIG. 8, conductive plate 134 is electrically connected to conductive layer 120. In some embodiments, conductive plate 134 and conductive layer 120 may be formed by the same process. In some embodiments, conductive plate 134 and conductive layer 120 may be formed by the same metal layer. In some embodiments, conductive plate 134 and conductive layer 120 may locate on different metal layers and further electrically connected by other via(s). In some embodiments, periphery circuit 130 may locate away from the memory cells, and conductive plate 134 and conductive layer 120 are electrically connected by the routing wires. For example, conductive plate 134 and conductive layer 120 may be electrically connected by the routing wires 133 shown in FIG. 5.

It is understood that even though the topmost conductive layer (conductive plate 134) in interconnection structure 132 is shown to connect conductive layer 120 in FIG. 8, other conductive layer(s) may also be applied in the present application to electrically connect the memory cells through the via structure and the conductive layer above dummy memory cell 128, and is not limited in the present application.

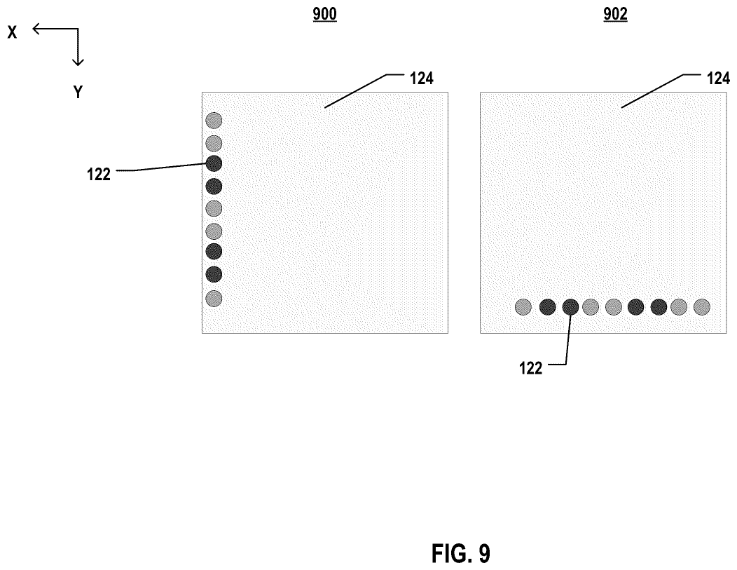

FIG. 9 illustrates plan views of exemplary ferroelectric memory devices 900 and 902, according to some aspects of the present disclosure. As shown in FIG. 9, ferroelectric memory devices 900 has dummy memory cells located on the left side of ferroelectric memory devices 900, and therefore conductive layer 124 and conductive layer 120 may be electrically connected through via structure 122 located on the left side of ferroelectric memory devices 900. In addition, as shown in FIG. 9, ferroelectric memory devices 902 has dummy memory cells located on the bottom side of ferroelectric memory devices 902, and therefore conductive layer 124 and conductive layer 120 may be electrically connected through via structure 122 located on the bottom side of ferroelectric memory devices 902. It is understood that the left side or the bottom side described here is used for better describing the corresponding locations of the via structures in the plane view of the ferroelectric memory devices, and any rotations or shift of the plan view may also be in the scope of the present application.

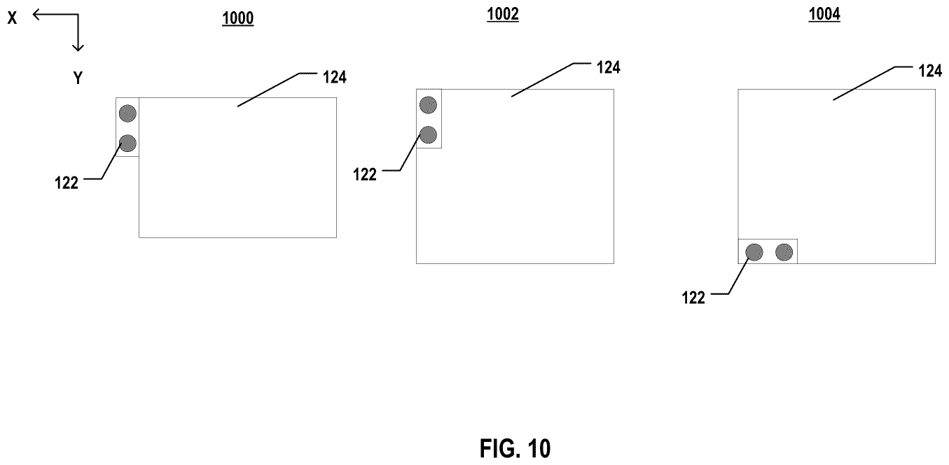

FIG. 10 illustrate plan views of exemplary ferroelectric memory devices 1000, 1002, and 1004, according to some aspects of the present disclosure. As shown in FIG. 10, ferroelectric memory devices 1000 have the routing interconnection structure formed outside the memory cell region and the via structures shown in FIGS. 1-3 may be applied here. In addition, as shown in FIG. 10, ferroelectric memory devices 1002 has dummy memory cells located on the left side of ferroelectric memory devices 1002, and therefore conductive layer 124 and conductive layer 120 may be electrically connected through via structure 122 located at the upper left corner of ferroelectric memory devices 1002. In another embodiment, as shown in FIG. 10, ferroelectric memory devices 1004 has dummy memory cells located on the bottom side of ferroelectric memory devices 1004, and therefore conductive layer 124 and conductive layer 120 may be electrically connected through via structure 122 located at the bottom left corner of ferroelectric memory devices 1004.

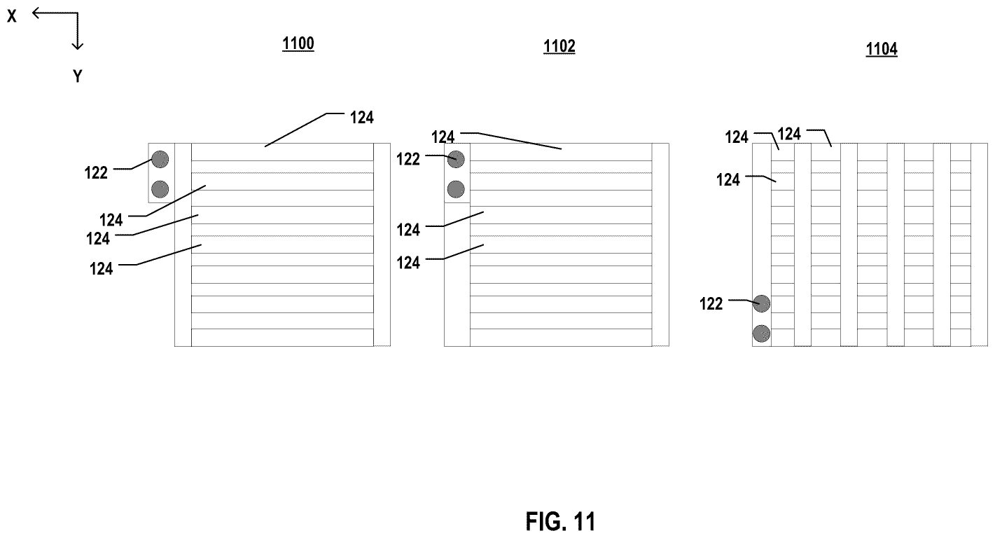

FIG. 11 illustrates plan views of exemplary ferroelectric memory devices 1100, 1102, and 1104, according to some aspects of the present disclosure. As shown in FIG. 11, in ferroelectric memory devices 1100, the memory cells located on the same row are covered by the same conductive layer 124. In other words, the memory cells located on different rows are covered by separated conductive layer 124 in ferroelectric memory devices 1100. In addition, ferroelectric memory devices 1100 has the routing interconnection structure formed outside the memory cell region and the via structures shown in FIGS. 1-3 may be applied here. Ferroelectric memory devices 1102 also has the memory cells located on different rows covered by separated conductive layer 124, and the dummy memory cells located on the left side of ferroelectric memory devices 1102. Conductive layer 124 and conductive layer 120 may be electrically connected through via structure 122 located at the upper left corner of ferroelectric memory devices 1102. Ferroelectric memory devices 1104 has separated conductive layer 124 covering different memory cells separately, and the dummy memory cells located on the left side of ferroelectric memory devices 1104. Conductive layer 124 and conductive layer 120 may be electrically connected through via structure 122 located at the bottom left corner of ferroelectric memory devices 1104, as shown in FIG. 11.

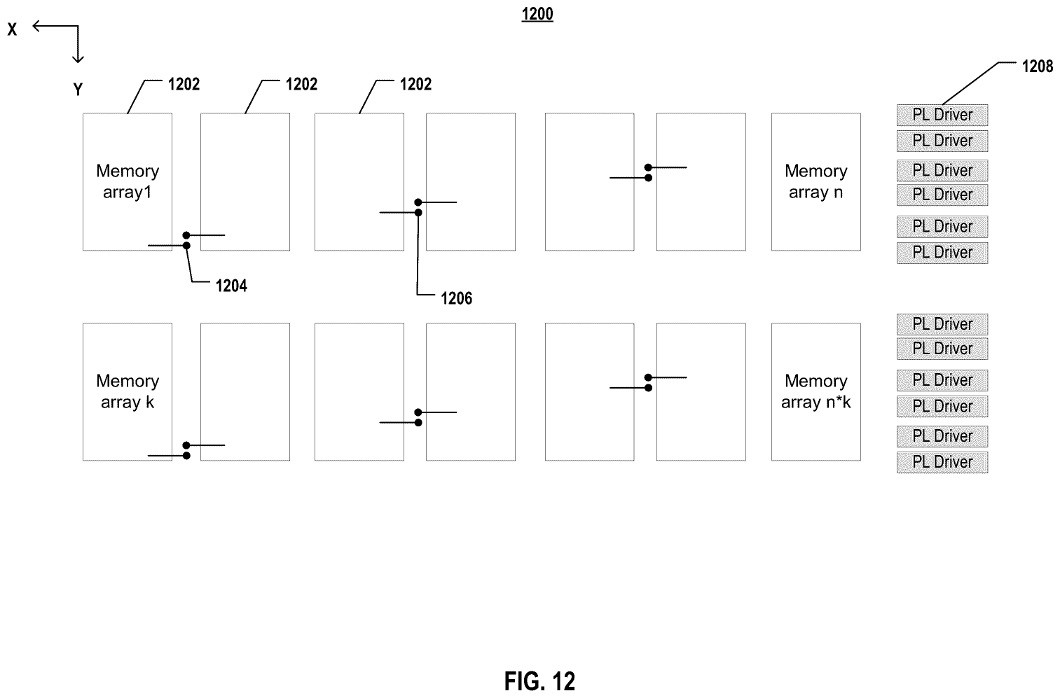

Various embodiments in FIGS. 9-11 are provided to show the flexibility of different locations and different routing paths of the present application, and those skilled in the art may make any changes based on the characteristics of the application. For example, FIG. 12 illustrates a plan view of an exemplary ferroelectric memory device 1200, according to some aspects of the present disclosure. Ferroelectric memory device 1200 has via structures 1204 and 1206, and the routing paths are formed between two memory cell regions 1202. Periphery circuits 1208 are located on the right side of memory cell regions 1202. Furthermore, the routing paths between different memory cell regions 1202 may be staggered. For example, via structure 1204 and via structure 1206 may be staggered on the y-direction in the plan view of ferroelectric memory device 1200, as shown in FIG. 12. By using the staggered layout, the routing paths beneath conductive layer 124 may occupy less area when connected to periphery circuits 1208.

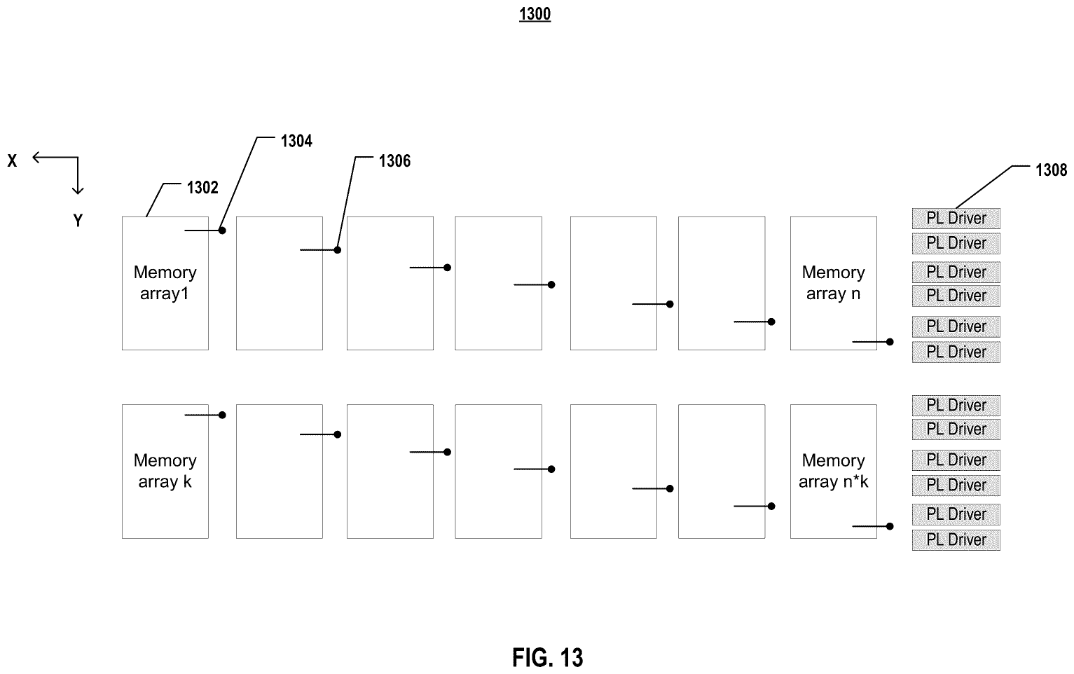

In another example, as shown in FIG. 13, which illustrates a plan view of an exemplary ferroelectric memory device 1300, according to some aspects of the present disclosure. Ferroelectric memory device 1300 has via structures 1304 and 1306, and the routing paths are formed aside each memory cell region 1302. Periphery circuits 1308 are located on the right side of memory cell regions 1302. Furthermore, the routing paths between different memory cell regions 1302 may be staggered. For example, via structure 1304 and via structure 1306 may be staggered on the y-direction in the plan view of ferroelectric memory device 1300, as shown in FIG. 13. By using the staggered layout, the routing paths beneath conductive layer 124 may occupy less area when connected to periphery circuits 1308.

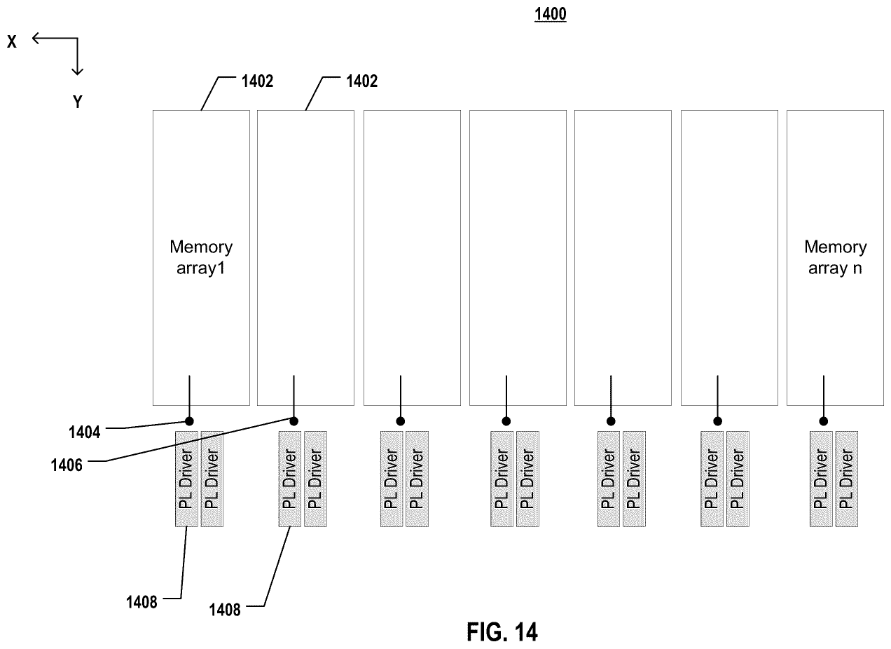

In a further example, FIG. 14 illustrates a plan view of an exemplary ferroelectric memory device 1400, according to some aspects of the present disclosure. Ferroelectric memory device 1400 has via structures 1404 and 1406, and the routing paths are formed below each memory cell region 1402. Periphery circuits 1408 are located below memory cell regions 1402.

Via structures 1404 and 1406 may be located on the bottom edge of each memory cell region 1402 between each memory cell region 1402 and each periphery circuit 1408, as shown in FIG. 14. By using this layout, the routing paths beneath conductive layer 124 may occupy less area.

As shown in FIGS. 12-14, the via structure may be disposed at the lateral area of the memory cell region. For example, as shown in FIGS. 12 and 13, via structures 1204 and 1304 may be disposed along the latitudinal direction at the lateral area of memory cell regions 1202 and 1302. For another example, as shown in FIG. 14, via structure 1404 may be disposed along the longitudinal direction at the lateral area of memory cell region 1402.

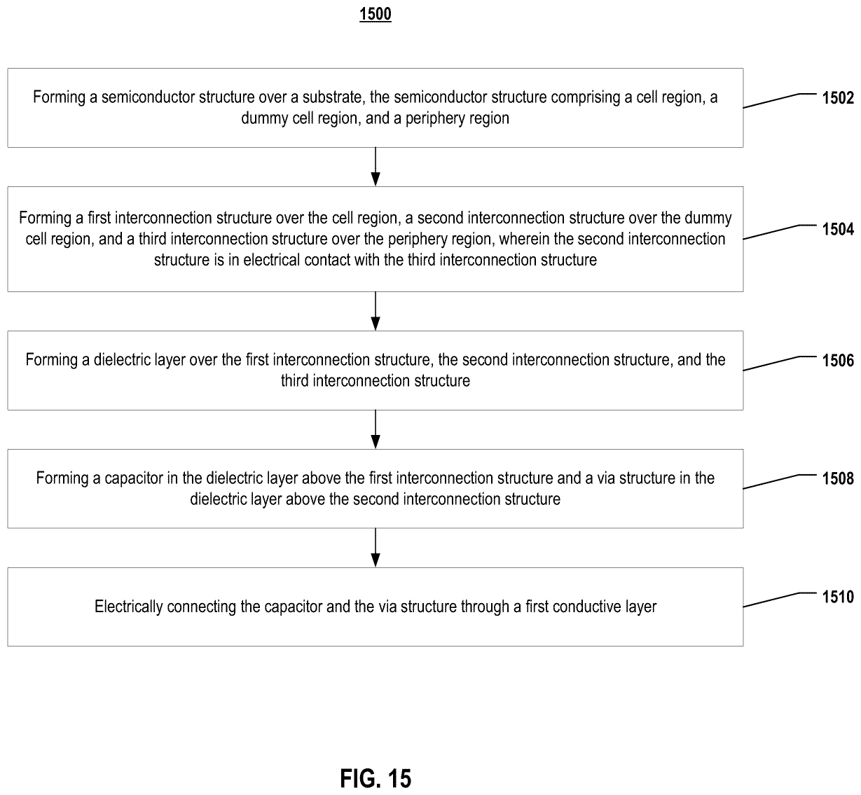

FIG. 15 illustrates a flowchart of an exemplary method 1500 for forming a memory device, according to some aspects of the present disclosure. For the purpose of better explaining method 1500, the cross-section of ferroelectric memory device 400 in FIG. 8 may be referred together.

As shown in FIG. 8 and operation 1502 of FIG. 15, a semiconductor structure is formed over a substrate 402. Substrate 402 may include silicon (e.g., single crystalline silicon), silicon germanium (SiGe), gallium arsenide (GaAs), germanium (Ge), silicon on insulator (SOI), or other suitable materials. The semiconductor structure may include memory cell 102, dummy memory cell 128, and periphery circuit 130.

The semiconductor structure may include transistors 106, 127, and 131, as shown in FIG. 8. Each of transistors 106, 127, and 131 may include a gate stack having a gate dielectric and a gate conductor formed on substrate 402, and source/drain regions are formed in substrate 402. The source/drain regions may be doped portions in the substrate with n-type or p-type dopants at a desired doping level. The gate dielectric may include dielectric materials, such as silicon oxide (SiOₓ), silicon nitride (SiNₓ) or high-k dielectric materials including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. The gate conductor may include conductive materials including, but not limited to, tungsten (W), cobalt (Co), copper (Cu), Al, polysilicon, silicide, or any combination thereof. The gate conductor may function as the word line of ferroelectric memory device 400.

As shown in FIG. 8 and operation 1504 of FIG. 15, interconnection structure 108, including conductive plate 110, may be formed over memory cell 102, conductive layer 120 may be formed above dummy memory cell 128, and interconnection structure 132, including conductive plate 134, may be formed over periphery circuit 130. Interconnection structure 108 and conductive plate 110 may be in contact with one of the source/drain regions and electrically coupled to electrode 116 of capacitor 112 formed in subsequent operations. In some embodiments, interconnection structure 108, conductive plate 110, conductive layer 120, interconnection structure 132, and/or conductive plate 134 may include Cu, titanium nitride (TiN), or W.

In some embodiments, dummy memory cell 128 may be located in the dummy cell region outside the edge of the cell region in a plan view of ferroelectric memory device 400. In some embodiments, conductive plate 110 may be located above interconnection structure 108. In some embodiments, conductive plate 110 may be the topmost conductive layer of interconnection structure 108. In some embodiments, another interconnection structure may be formed above dummy memory cell 128, and conductive layer 120 may be the topmost conductive layer of this interconnection structure. In some embodiments, conductive plate 110 and conductive layer 120 are the same conductive layer located beneath conductive layer 124. In some embodiments, conductive plate 110 and conductive layer 120 are formed in the same process. In some embodiments, conductive plate 110 and conductive layer 120 may include the same material. In some embodiments, the top surfaces of conductive plate 110 and conductive layer 120 may be flush with each other.

As shown in FIG. 8 and operation 1506 of FIG. 15, a dielectric layer 404 may be formed over conductive plate 110, conductive layer 120, and conductive plate 134, and then, capacitor 112 may be formed in dielectric layer 404 above conductive plate 110, and via structure 122 may be formed above conductive layer 120, as shown in operation 1508 of FIG. 15.

In some embodiments, dielectric layer 404 may include an interlayered dielectric (ILD) layer, such as SiOₓ or SiNₓ. In some embodiments, capacitor 112 is formed in dielectric layer 404 before the formation of via structure 122. In some embodiments, via structure 122 is formed in dielectric layer 404 before the formation of capacitor 112. In some embodiments, capacitor 112 and via structure 122 are formed in dielectric layer 404 during the same manufacturing processes. Capacitor 112 may include electrode 114, and electrode 116 surrounding at least a portion of electrode 114. In some embodiments, electrode 116 electrically contacts conductive plate 110. In some embodiments, electrode 116 directly contacts conductive plate 110. Ferroelectric layer 118 is disposed between electrode 114 and electrode 116. In some embodiments, the height of capacitor 112 is less than or equal to the height of via structure 122. In some embodiments, the height of capacitor 112 is less than the height of a stack of via structure 122 and conductive layer 124.

Electrode 116, ferroelectric layer 118, and electrode 114 are sequentially formed in dielectric layer 404, and electrode 116 electrically contacts conductive plates 110. In some embodiments, electrode 114 and electrode 116 may include TiN, titanium silicon nitride (TiSiNₓ), titanium aluminum nitride (TiAlNₓ), titanium carbon nitride (TiCNₓ), tantalum nitride (TaNₓ), tantalum silicon nitride (TaSiNₓ), tantalum aluminum nitride (TaAlNₓ), tungsten nitride (WNₓ), tungsten silicide (WSiₓ), tungsten carbon nitride (WCNₓ), ruthenium (Ru), ruthenium oxide (RuOₓ), iridium (Ir), doped polysilicon, transparent conductive oxides (TCO), iridium oxide (IrOₓ), or other suitable materials. In some embodiments, electrode 114 and electrode 116 may include the same material(s). In some embodiments, electrode 114 and electrode 116 may include different materials.

In some embodiments, electrode 114 and electrode 116 may be formed by atomic layer deposition (ALD), physical vapor deposition (PVD), chemical vapor deposition (CVD), electrochemical deposition, pulsed laser deposition (PLD), or other suitable processes. In some embodiments, electrode 114 and electrode 116 may have a thickness between about 2 nm and about 50 nm. In some embodiments, electrode 114 and electrode 116 may have the same thickness. In some embodiments, electrode 114 and electrode 116 may have different thicknesses.

In some embodiments, ferroelectric layer 118 may include a ferroelectric oxide material. The ferroelectric oxide may be doped with a plurality of dopants, which can improve ferroelectric film crystallization. For example, the dopants may provide elasticity during the crystallization of the doped ferroelectric layer, reducing the number of defects formed in the ferroelectric film crystallization, and improving high-K ferroelectric phase formation. It is understood that in some embodiments, ferroelectric layer 118 may include a multi-layer structure.

In some embodiments, ferroelectric layer 118 may include a ferroelectric composite oxide. In some embodiments, ferroelectric layer 118 may include oxygen and one or more ferroelectric metals. The ferroelectric metals can include, but not limited to, zirconium (Zr), hafnium (Hf), titanium (Ti), aluminum (Al), or other suitable materials. In some embodiments, ferroelectric layer 118 may include oxygen and two or more ferroelectric metals. In some embodiments, ferroelectric layer 118 may include oxygen and a non-metal material such as silicon (Si).

Optionally, ferroelectric layer 118 may also include a plurality of dopants formed as a part of the crystal structures. In some embodiments, the dopants compensate for the defects formed during the crystallization of the ferroelectric oxide material to improve the film quality of ferroelectric layer 118. In some embodiments, the dopants are different from the ferroelectric metals in the ferroelectric oxide material and include one or more dopants from one or more of Hf, Zr, Ti, Al, Si, hydrogen (H), oxygen (O), vanadium (V), niobium (Nb), tantalum (Ta), yttrium (Y), and/or lanthanum (La).

As shown in FIG. 8 and operation 1510 of FIG. 15, conductive layer 124 is formed over electrode 114 and via structure 122, and electrode 114 and via structure 122 are electrically connected through conductive layer 124. In some embodiments, conductive layer 124 is directly formed over electrode 114. In some embodiments, conductive layer 124 is electrically connected to electrode 114 through a via structure.

By electrically connecting conductive layer 124 and conductive layer 120 through via structure 122, the routing path may be designed through conductive layer, e.g., layer Mₙ, beneath the topmost conductive layer, e.g., layer Mₙ₊₁. Furthermore, by electrically connecting conductive layer 124 and conductive layer 120 through via structure 122, capacitor 112 may be formed between the topmost conductive layer, e.g., layer Mₙ₊₁, and the penultimate conductive layer, e.g., layer Mₙ, and electrode 114 can have a routing path through conductive layer 124, via structure 122, and conductive layer 120.

Typically, the topmost metal structure, including via structure 122, of routing interconnection structure 104 or the periphery circuit has the largest thickness among other metal structures. When forming capacitor 112 in the area corresponding to the topmost conductive layer, e.g., layer Mₙ₊₁, and the penultimate conductive layer, e.g., layer Mₙ, capacitor 112 may have a larger cell area and enough charge for memory sensing. Capacitor 112 is, therefore, may be disposed in the area corresponding to one single metal structure layer instead of occupying multiple layers of metal structure. By using this structure, the manufacturing process may be simplified, and the reliability of the memory cells may also be improved.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Embodiments of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all exemplary embodiments of the present disclosure as contemplated by the inventor(s), and thus, are not intended to limit the present disclosure and the appended claims in any way.

The breadth and scope of the present disclosure should not be limited by any of the above-described exemplary embodiments, but should be defined only in accordance with the following claims and their equivalents.

What is claimed is:

1. A memory device, comprising:
a plurality of memory cells, each memory cell comprising:
at least one first transistor;
a cell interconnection structure formed over the at least one first transistor and in electrical contact with the at least one first transistor, the cell interconnection structure comprising a cell plate disposed at a top layer of the cell interconnection structure; and
at least one capacitor electrically coupled to the at least one first transistor through the cell interconnection structure, each capacitor comprising:
a first electrode;
a second electrode surrounding at least a portion of the first electrode, the second electrode electrically contacting the cell plate; and
a ferroelectric layer disposed between the first electrode and the second electrode; and
a routing interconnection structure in electric contact with the plurality of memory cells, comprising:
a first conductive layer; and
a first via structure disposed on the first conductive layer,
wherein the first via structure is in electrical contact with the first electrode through a second conductive layer; and
wherein the first conductive layer is beneath the second conductive layer.

2. The memory device of claim 1, wherein the second conductive layer is disposed on and in direct contact with the first electrode.

3. The memory device of claim 1, wherein the second conductive layer is disposed on and in electric contact with the first electrode through a second via structure.

4. The memory device of claim 1, wherein the cell plate and the first conductive layer are formed in a same manufacturing process.

5. The memory device of claim 1, further comprising:
a periphery circuit configured to control operations of the plurality of memory cells, comprising:
at least one second transistor; and
a periphery interconnection structure electrically coupled to the at least one second transistor,
wherein a third conductive layer of the periphery interconnection structure is in electric contact with the first conductive layer.

6. The memory device of claim 5, wherein the third conductive layer and the first conductive layer are extended and directly connected to each other.

7. A memory device, comprising:
a plurality of memory cells, each memory cell comprising:
at least one first transistor;
a cell interconnection structure formed over the at least one first transistor and in electrical contact with the at least one first transistor, the cell interconnection structure comprising a cell plate disposed at a top layer of the cell interconnection structure; and
at least one capacitor electrically coupled to the at least one first transistor through the cell interconnection structure, each capacitor comprising:
a first electrode;
a second electrode surrounding at least a portion of the first electrode, the second electrode electrically contacting the cell plate; and
a ferroelectric layer disposed between the first electrode and the second electrode; and
a dummy memory cell, comprising:
at least one second transistor;
a first conductive layer disposed above the at least one second transistor; and
a first via structure disposed on the first conductive layer,
wherein the first via structure is in electrical contact with the first electrode through a second conductive layer; and
wherein the first conductive layer is beneath the second conductive layer.

8. The memory device of claim 7, wherein the first via structure overlaps the dummy memory cell in a plan view of the memory device.

9. The memory device of claim 7, wherein the second conductive layer is disposed on and in direct contact with the first electrode.

10. The memory device of claim 7, wherein the second conductive layer is disposed on and in electric contact with the first electrode through a second via structure.

11. The memory device of claim 7, wherein the cell plate and the first conductive layer are formed in a same manufacturing process.

12. The memory device of claim 7, further comprising:
a periphery circuit configured to control operations of the plurality of memory cells, comprising:
at least one third transistor; and
a periphery interconnection structure electrically coupled to the at least one third transistor,
wherein a third conductive layer of the periphery interconnection structure is in electric contact with the first conductive layer.

13. The memory device of claim 12, wherein top surfaces of the third conductive layer and the first conductive layer are flush with each other.

14. The memory device of claim 12, wherein the third conductive layer and the first conductive layer are extended and directly connected to each other.

15. A method for forming a ferroelectric memory, comprising:
forming a semiconductor structure over a substrate, the semiconductor structure comprising a cell region, a dummy cell region, and a periphery region;
forming a first interconnection structure over the cell region, a second interconnection structure over the dummy cell region, and a third interconnection structure over the periphery region, wherein the second interconnection structure is in electrical contact with the third interconnection structure;
forming a dielectric layer over the first interconnection structure, the second interconnection structure, and the third interconnection structure;
forming a capacitor in the dielectric layer above the first interconnection structure and a via structure in the dielectric layer above the second interconnection structure; and
electrically connecting the capacitor and the via structure through a first conductive layer.

16. The method of claim 15, wherein the capacitor comprises a first electrode, a second electrode surrounding at least a portion of the first electrode, and a ferroelectric layer disposed between the first electrode and the second electrode; and the first conductive layer is in direct contact with the first electrode.

17. The method of claim 16, wherein electrically connecting the capacitor and the via structure through the first conductive layer, further comprises:
forming the first conductive layer over a plurality of capacitors in direct contact with a plurality of first electrodes of the plurality of capacitors, and over the via structure in direct contact with the via structure.

18. The method of claim 15, wherein forming the first interconnection structure over the cell region, the second interconnection structure over the dummy cell region, and the third interconnection structure over the periphery region, further comprises:
forming a cell plate on a topmost layer of the first interconnection structure; and
forming a second conductive layer on a topmost layer of the second interconnection structure,
wherein top surfaces of the cell plate and the second conductive layer are flush with each other.

19. The method of claim 15, wherein the dummy cell region is outside an edge of the cell region in a plan view of the semiconductor structure.

20. The method of claim 15, wherein a first height of the capacitor is equal to or less than a second height of a stack of the via structure and the first conductive layer.
